(19) United States
(12) Patent Application Publication
(10) Pub. No.: US 2009/0026471 A1
(43) Pub. Date: Jan. 29, 2009

(54) LIGHT-SCATTERING STRUCTURE, LIGHT EMITTING DEVICE COMPRISING THE SAME AND METHOD OF FORMING THE SAME

(75) Inventors: Han-Min Wu, Taoyuan County (TW); Lung-Han Peng, Taipei City (TW)

Correspondence Address: WPAT, PC;INTELLECTUAL PROPERTY ATTORNEYS, 2030 MAIN STREET, SUITE 1300, IRVINE, CA, 92614, US

(73) Assignee: NOETON OPTOELECTRONICS CORP., Taipei City (TW)

(21) Appl. No.: 11/829,651

(22) Filed: Jul. 27, 2007

(51) Int. Cl. H01L 33/00; G02F 1/1335; H01S 5/00

(52) U.S. Cl. 257/98; 216/24; 349/62; 372/50.1; 257/E33.001

(57) ABSTRACT

A light-scattering structure with micron-scale or submicron-scale protruding portions is provided to improve the light extraction efficiency of light emitting devices. The protruding portions function as scattering sites and can be assembled closely. A method of forming a light-scattering structure is also provided, wherein all the conventional substrate materials can be used for the substrate of the light-scattering structure, and scattering sites of submicron-scale, micron-scale or larger size can be fabricated.

### FIELD OF INVENTION

The present invention relates to a light-scattering structure, and more particularly to a light-scattering structure comprising protruding portions each having a width less than 10 microns.

### BACKGROUND

In a light emitting device, such as a light emitting diode (LED), the light extraction efficiency is limited by total internal reflections caused by a large difference in refractive indices of the semiconductors and the surrounding medium. As taught by A. David et al., “Photoinc-crystal GaN light-emitting diodes with tailored guided modes distribution” Appl. Phys. Lett. 88, 061124 (2006), for a planar shape of gallium nitride (GaN) LED on a sapphire substrate, 66% of the generated light is trapped in the GaN layer by total internal reflections at the interface of air/GaN and GaN/sapphire whereas another 22% of the generated light is trapped by total internal reflections in the sapphire substrate. For a refractive index of the ambient nₐ and the semiconductor nₛ, an escape cone expanding a critical angle of sin θ_{c}=nₐ/nₛ would allow a fraction [(1−cos θ_{c}/2)]·[1−(nₐ−nₛ)²/(nₐ+nₛ)²]˜6% of light transmitted from the semiconductor to the ambient. Therefore only approximately 6% of the light generated are extracted from the top and bottom face of a GaN LED. It can be concluded that the light extraction efficiency depends on the macroscopic geometry and surface structure of the GaN LED.

The light extraction efficiency can be improved by means of redirecting the light propagation direction by imposed a scattering surface to reduce the lights entering into the zone of total internal reflections. The larger the area of the scattering surface is imposed, the larger the improvement of the light extraction efficiency can be made. U.S. Pat. No. 6,870,191 taught a method of growing GaN LED on a substrate with recess and/or protruding portions to scatter or diffract light generated in the light emitting region. In this method, the unevenness in a substrate is created by etching a two-dimensional (2D) pattern on a SiO₂ overlayer deposited onto the substrate. However, the size and the intervals between the recess and/or protruding portions are constrained by the lithographic resolution. These would limit the increase and the availability of scattering surface imposed by this method.

U.S. Pat. Nos. 5,779,924 and 7,098,589 and J. J. Wierer et al., “InGaN/GaN quantum-well heterostructure light-emitting diodes employing photonic crystal structures” Appl. Phys. Lett. 84 (19), pp. 385-3887 (2004) also taught methods of using ordered structures of 2D surface texturing, or photonic crystal as diffraction gratings. These ordered 2D structures offer a phase-matching momentum in the horizontal plane of a LED to couple the trapped light into the radiation modes. These ordered 2D structures are characterized with a periodical distribution of air-holes in a dielectric or semiconductor surface layer and have a critical feature size and pitch around an optical wavelength. However, the implementation of these structures requires sophisticated lithographic and etching processes to achieve a desirable patterning. Therefore, it is difficult to achieve mass-production, and the density of the growth sites is limited by the resolution of lithographic and etching process.

US 2005/0277218A1 taught a method of forming convex part of rugged surface on the uppermost layer to widen the average critical angle of an LED. This method requires a selective growth of convex shape (i.e., pyramid) of group III nitride on the window portions of a mask layer over a p-GaN layer of a LED structure. Here again the density of theses growth sites is limited by the resolution of lithographic and etching process.

In another prior art, i.e., E. G. Dierschke et al., “Efficient electroluminescence from zinc diffused GaAlAs diodes at 25° C.,” Appl. Phys. Lett. 19 (4), pp. 98-100 (1971), the light extraction efficiency was improved by grounding a LED into a hemispherical shape. The underlying physics is that light emitted from a point in the active region of a hemispherically-shaped LED can intersect the hemispherical surface at a nearly normal incident configuration. This in turn reduces the probability for the event of total internal reflection to occur. However, such macroscopic shaping scheme is tedious and cost of materials.

In U.S. Pat. No. 7,064,355, a high refractive index of hemispherical lens was bonded to a LED by applying a pressure at an elevating temperature. This process again is tedious and difficult for mass-production. Alternatively, another prior art, i.e., D. Kim et al., “Effect of GaN Microlens array on efficiency of GaN-based blue light emitting diode,” Jpn. J. Appl. Phys. 44 (1), pp.L18-L20 (2005), taught the integration of micro-lens with a GaN LED to increase the light extraction efficiency. Quality factors related to the evaluation of the micro-lens are a larger surface filling factor and a control of lens curvature on suitable substrates that are difficult to achieve by the abovementioned method.

In U.S. Pat. No. 5,618,474 and Z. L. Liau, Mater. Sci. Eng. R42, 41 (2003), the micro-lenses were fabricated by first forming a specific etched pattern on the semiconductor surface followed by a high temperature mass-transportation process to modify the surface energy and transform the etched semiconductor pattern into a lens shape. In another prior art, i.e., U.S. Pat. No. 4,689,291 and Z. D. Popovic, R. A. Sprague, and G. A. N. Connell, Appl. Opt. 27, 1281 (1988), a photoresist cylinder pattern was first developed on a substrate followed by heating above the glass temperature to allow the melt and reflow of photoresist to form a lens shape. These processing methods invoke the use of photolithographic equipment that limits the size, shape, and filling factor of the micro-lens on the substrate surface.

It is known that if the scattering sites imposed on a substrate surface are made smaller, the available scattering surface is increased, and thus the improvement of light extraction efficiency is higher. However, all prior art technologies are unable to produce a light-scattering structure with micron-scale scattering sites, due to the restrictions of their processing and equipments. In addition, due to the processing restrictions of prior art technologies, the materials used for the substrate of the light-scattering structure are also limited.

### SUMMARY OF INVENTION

The present invention provides a light-scattering structure with micron-scale or submicron-scale protruding portions. The protruding portions function as scattering sites and can be assembled closely. Therefore, the present invention can significantly improve the light extraction efficiency of light emitting devices. In addition, the present invention provides a method of forming a light-scattering structure. In the method of the present invention, all the conventional substrate materials can be used for the substrate of the light-scattering structure. Furthermore, the method of the present invention can not only be used to manufacturing a light scattering structure with micron-scale or submicron-scale scattering sites, but also can be used to manufacturing a light scattering structure with larger scattering sites.

The light-scattering structure of the present invention can be included in a light emitting diode (LED), a semiconductor laser device, a backlight system or any light emitting devices to improve the light extraction efficiency.

According to an embodiment of the present invention, a light-scattering structure comprises a plurality of protruding portions on a surface of a substrate, wherein at least one of said plurality of protruding portions has a width less than 10 microns.

According to another embodiment of the present invention, a method of forming a light-scattering structure comprises the steps of placing a plurality of particles on a substrate and etching said particles and said substrate to form a plurality of protruding portions on said substrate.

### BRIEF DESCRIPTION OF DRAWINGS

FIGS. 1A to 1C are the schematic diagrams of forming a scattering structure according to a preferred embodiment of the present invention, and FIG. 1D shows the relationship between the forming steps illustrated in FIGS. 1A, 1B and 1C.

FIG. 2 shows several SEM micrographs (a)-(d) revealing the steps for forming 0.35 μm size GaN lenses with an increase of the ICP-RIE dry etching time.

FIG. 3 shows several SEM micrographs revealing the formation of 0.35 μm lenses on (a) GaN, (b) ITO and (c) SiO₂ substrates respectively.

FIG. 4 illustrates the measured L-I and I-V curves of 1 μm-lens LED, random lens LED, and ordered lens LED.

### DETAILED DESCRIPTION OF THE PREFERRED EMBODIMENT

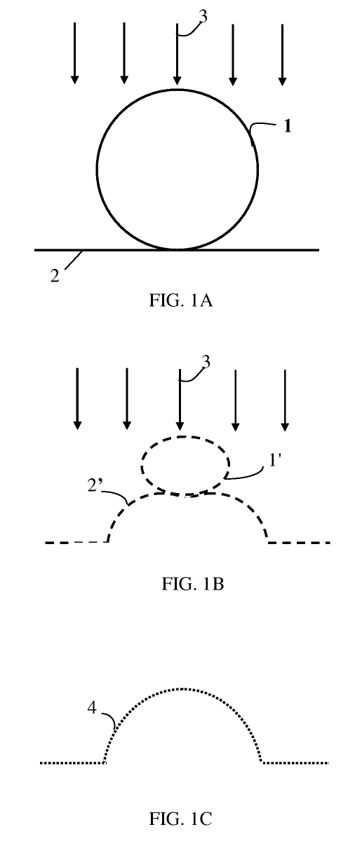

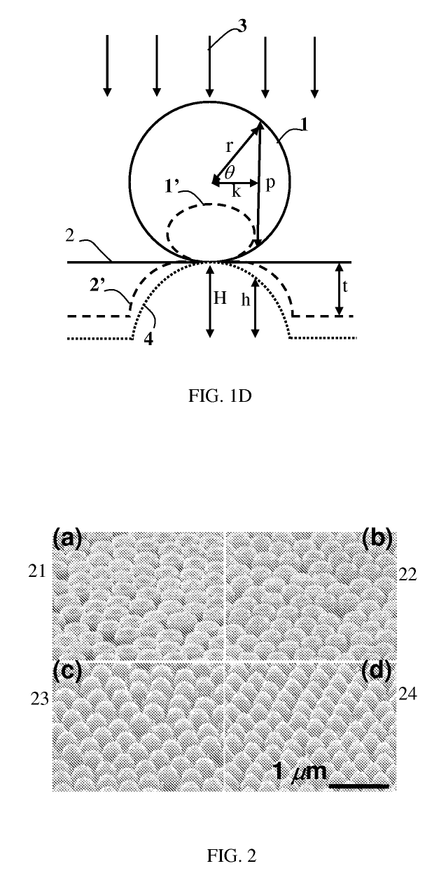

Please refer to FIGS. 1A to 1C. FIGS. 1A to 1C are the schematic diagrams of forming a scattering structure according to one embodiment of the present invention. FIG. 1A shows that a polystyrene sphere (PS) 1 is placed on a substrate 2, wherein the PS 1 and the substrate 2 are etched with an etching process treated with a gas 3, wherein the PS 1 and the substrate may have different etch rate. FIG. 1B reveals the PS 1′ and the substrate 2′ during the etching process, wherein the PS 1′ is shrunk and eventually disappears in the etching process. In FIG. 1B, it is clear that the substrate 2 forms a protruding surface 2′ due to the masking and self-etching effects provided by the polystyrene sphere during the etching process. After a predetermined etch time, the remaining debris of PS 1′ can be removed by dissolving in a chemical solution, so that the protruding portion 2′ is formed. Alternatively, with increased etch time to completely etch away the PS, a protruding portion 4 formed after the etching process is shown in FIG. 1C. If the PS 1 has a size of micron-scale or submicron-scale, the protruding portion formed on the substrate 2 will also has a size of micron-scale or submicron-scale. According to the method of the present invention, masking particles with a size larger than 10 microns can also be used to form to light scattering structure.

In the embodiment shown in FIGS. 1A to 1C, polystyrene spheres are used as the masking particles in the etching process. According to the present invention, particles of different shapes can be used as the masking particles to forming the light scattering structure.

According to the present invention, the shape of the protruding portions is determined by the shape of the masking particles, the etch time and the ratio of the etch rate of the substrate to that of the masking particles.

According to the present invention, the light scattering structure can be formed directly on a substrate or be formed on a layer directly or indirectly adhered to the substrate.

The light-scattering structure of the present invention can be included in a light emitting diode (LED), a semiconductor laser device, a backlight system or any light emitting devices to improve the light extraction efficiency.

With reference to FIG. 1D, which shows a polystyrene (PS) sphere 1 was initially self-assembled on the surface of substrate 2. Let an etch selectivity parameter S be defined as the etch rate ratio between the PS and the substrate when these materials were treated with reactive etching gas 3. After a predetermined etch time, the remaining debris of PS 1′ can be removed by dissolving in a chemical solution. A terraced cylinder structure 2′ with radius of k and height of t was fabricated, where k and t is given by

k=r cos θ, and t=2rS sin θ

With increased etch time to completely etch away the monolayer of PS spheres and in the meanwhile to polish the rough defected surface, the fabrication of protruding portion 4, which functions as a micro-lens was successfully achieved. To evaluate the profile of the fabricated micro-lens, a linear relation can be found between the etched spheres thickness p and the micro-lens height h at the same spot, which yields

h=p×S=2rS sin θ

According to this relation, we can conclude that the shape of fabricated micro-lens was similar to prolate hemispheroids with long axis as the height H=2rS and short axis as the radius r. When the etch parameter S is larger than 0.5, an etch profile of ellipsoid shape can be formed. When the parameter S is 0.5, a spherical etch profile with radius of curvature equal to r can be developed on the substrate surface. When the etch parameter S is smaller than 0.5, a spherical etch profile, whose radius of curvature ρ can be approximately expressed as ρ=(4rS²+r)/4S, can be developed on the substrate surface.

In one embodiment, a patterned template, consisting of a monolayer of self-assembled PS with submicron size of diameter and in a form of two-dimensional (2D) close-packed structure, was formed on the surface of gallium nitride (GaN) substrate. The PS patterned template then served as an etch mask during a subsequent dry etching procedure. After a predetermined etch time, the etch rate difference between the uncovered substrate and the PS covered region can develop a 2D array of close-packed, parabolic shape of submicron lens on the surface of GaN.

In another embodiment, a patterned template, consisting of a monolayer of self-assembled PS with submicron size of diameter and in a form of two-dimensional (2D) close-packed structure, was formed on the surface of gallium nitride (GaN) substrate. The PS patterned template then served as an etch mask during a subsequent dry etching procedure. By modifying the etching gases and etching parameters to obtain different etch selectivity between PS and GaN, a 2D array of close-packed, ellipsoid and spherical shape of submicron lenses on the surface of GaN was achievable.

In a third embodiment, a patterned template, consisting of a monolayer of self-assembled PS with submicron size of diameter and in a form of 2D close-packed structure, was formed on the surface of indium tin oxide (ITO) covered GaN substrate. The PS patterned template then served as an etch mask during a subsequent dry etching procedure. After a predetermined etch time, the etch rate difference between the uncovered ITO dielectric and the PS covered region can develop a 2D array of close-packed, sphere shape of submicron lens on the surface of ITO.

In a fourth embodiment, a patterned template, consisting of a monolayer of self-assembled PS with submicron size of diameter and in a form of 2D close-packed structure, was formed on the surface of silicon dioxide (SiO₂) covered GaN substrate. The PS patterned template then served as an etch mask during a subsequent dry etching procedure. After a predetermined etch time, the etch rate difference between the uncovered SiO₂ dielectric and the PS covered region can develop a 2D array of close-packed, sphere shape of submicron lens on the surface of SiO₂.

The PS spheres used in these experiments are in the form of 5 wt % water suspension. The GaN wafers were first cleaned by immersing in acetone, isopropyl alcohol (IPA), and deionized water with ultrasonic agitation for 10 min, respectively, followed by immersing in a diluted surfactant solution for 30 min to further increase the wafer's wetting ability. After the surface treatments, the PS/water suspension was dropped onto the cleaned substrates. By this method, a monolayer of PS spheres of 0.35 and 1 μm can be successfully assembled on the surface of the GaN substrate in a 2D close-packed hexagonal pattern with occasional appearance of defect-like or dislocation-like voids.

Subsequently, the substrates capped with a monolayer of PS spheres were subjected to the treatments of inductively coupled plasma reactive ion etch (ICP-RIE) dry-etching process to complete the fabrication of micro-lens on the GaN layers. During the etch process, substrates 2 and PS spheres 1 were both etched by the high-energy plasma 3. As a result the etched substrates would take up a hemispherical shape 4 since the etch mask of PS spheres was gradually shrunk 1′. The dry etching process was performed on the GaN substrate capped with 0.35 μm PS spheres by applying different etch time while keeping other etch parameters such as BIAS power, ICP power, mixed ratio of gases of Cl₂/Ar, and chamber pressure at 80 W, 200 W, 9:1 and 10 Pa.

When the etching process started, a microdisk shape of GaN structures 21 shown in FIG. 2(a) was first formed since the substrate was etched by a shallow depth and most of the top surface was still protected by the remained PS spheres. With increase of etching time, the PS spheres kept shrinking where masking effect above the substrate to be etched deeper and formed terraced structures 22 as depicted in FIG. 2(b). As the etched side of the PS spheres shrunk, microlens-like structure 23 were formed on the GaN surface but had some whisker-like defects remained on the surface as shown in FIG. 2(c). Finally, by applying more etch time to completely etch away the monolayer PS spheres and in the meanwhile to polish the rough defected surface, the fabrication of microlens was successfully achieved as represented by the 0.35 μm size of GaN lenses 24 illustrated in FIG. 2(d). These 0.35 μm size GaN lenses 24, arranged in a 2D close-packed pattern due to an etch pattern transferred from the self-assembled spheres, exhibited an intact convex shape and smooth surface without any deformation or defect. When measured by an atomic force microscopy (AFM), the surface morphology scanning images revealed a root mean square roughness of 0.5 nm for the etched surface, indicating that the etched surface can still maintain a high optical quality after the ICP-RIE dry-etching process.

The radius and height of the 0.35 μm size GaN lenses 24 formed by the Cl₂/Ar etching gases recipe shown in FIG. 2(d) were 0.175 and 0.3 μm, respectively, as measured by AFM. These data gave an effective etch selectivity of 0.86 between the GaN substrate and the PS sphere. Since the etch parameter S is larger than 0.5, the fabricated micro-lenses were hemispheroids with an ellipsoid-shape profile.

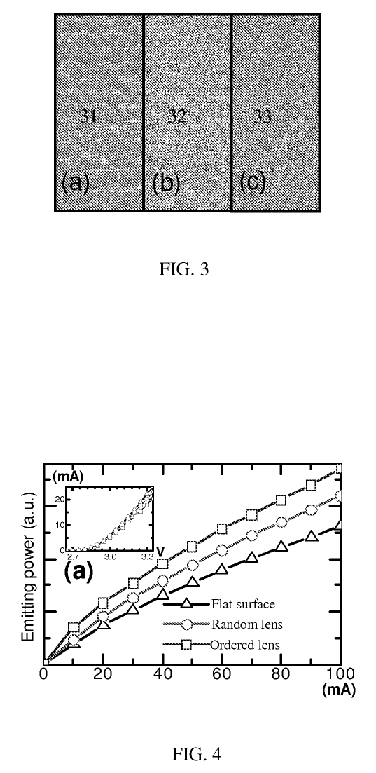

In another embodiment, 0.35 μm size GaN lenses 31 with smaller height of 0.08 μm are fabricated, as shown in FIG. 3(a), by applying an other etching gas of CHF₃/Ar gases with a gas mix ratio of CHF₃/Ar=7/1. The calculated etch selectivity of 0.23 was smaller than 0.5 indicating the shape of the micro-lens shape was very similar to that of a sphere surface. By the equation of ρ=(4rS²+r)/4S, a corresponding radius of curvature p equal to be 0.23 μm can be found.

In another embodiment, 0.35 μm size ITO lenses 32 with smaller height of 0.045 μm are fabricated, as shown in FIG. 3(b), by applying another etching gas recipe of Cl₂/Ar gases with a gas mix ratio of Cl₂/Ar=9/1. The calculated etch selectivity of 0.13 was smaller than 0.5 indicating the shape of the corresponding micro-lens was very similar to that of a sphere surface. By the equation of ρ=(4rS²+r)/4S, a radius of curvature ρ of 0.36 μm was obtained.

In another embodiment, 0.35 μm size SiO₂ lenses 33 with smaller height of 0.091 μm are fabricated, as shown in FIG. 3(c), by applying another etching gas recipe of CHF₃/Ar gases with a gas mix ratio of CHF₃/Ar=7/1. The calculated etch selectivity of 0.26 was smaller than 0.5 indicating the shape of the micro-lens was very similar to that of a sphere surface. By the equation of ρ=(4rS²+r)/4S, a radius of curvature ρ of 0.22 μm was obtained.

A set of GaN LEDs were made under the condition of a flat surface, a random-texturing surface, and an ordered texturing surface with 1 μm size of close-packed micro-lens made of ITO, respectively. Data shown in FIG. 4 indicate that averagely 40% enhancement (over 20 devices) in light output power was found in the micro-lens LEDs, compared with conventional planar surface LEDs at 20 mA dc current. This improvement was higher than the one of 28% enhancement found in the LEDs with textured ITO surface fabricated with a random-texturing surface.

The embodiments of the present invention are detailed above. The scope of the present invention is not limited to the details of those embodiments and should cover any modifications and changes which can be directly deduced by persons skilled in the art from the disclosure and teaching of the present invention.

What is claimed is:

1. A light-scattering structure, comprising:
a plurality of protruding portions on a surface of a substrate;
wherein at least one of said plurality of protruding portions has a width less than 10 microns.

2. The light-scattering structure of claim 1, wherein said plurality of protruding portions are assembled.

3. The light-scattering structure of claim 1, wherein said width is less than one micron.

4. A light emitting diode (LED) device, comprising:
a light-scattering layer; and
a plurality of protruding portions formed on a surface of said light-scattering layer;
wherein at least one of said plurality of protruding portions has a width less than 10 microns.

5. The light emitting diode (LED) device of claim 4, wherein said light-scattering layer is a substrate of said light emitting diode.

6. The light emitting diode (LED) device of claim 4, wherein said width is less than one micron.

7. A semiconductor laser device, comprising
a light-scattering layer; and
a plurality of protruding portions formed on a surface of said light-scattering layer;
wherein at least one of said plurality of protruding portions has a width less than 10 microns.

8. The semiconductor laser device of claim 7, wherein said light-scattering layer is a substrate of said semiconductor laser device.

9. The semiconductor laser device of claim 7, wherein said width is less than one micron.

10. A backlight system, comprising:
a light-scattering plate; and
a plurality of protruding portions formed on a surface of said light-scattering plate;
wherein at least one of said plurality of protruding portions has a width less than 10 microns.

11. The backlight system of claim 10, wherein said width is less than one micron.

12. A method of forming a light-scattering structure, comprising:
placing a plurality of particles on a substrate; and
etching said particles and said substrate to form a plurality of protruding portions on said substrate.

13. The method of claim 12, wherein said particles are of spherical shape.

14. The method of claim 12, wherein the size of said particles is less than 10 microns.

15. The method of claim 12, wherein the size of said particles is less than one micron.

16. The method of claim 12, wherein said particles are assembled on said substrate.

17. The method of claim 12, wherein the shape of said protruding portions is determined by the shape of said particles, the etch time and the ratio of the etch rate of said substrate to the etch rate of said particles.
